(19) United States
(12) Patent Application Publication
(10) Pub. No.: US 2012/0241934 A1
(43) Pub. Date: Sep. 27, 2012

(54) SEMICONDUCTOR APPARATUS AND METHOD FOR MANUFACTURING THE SAME

(75) Inventor: Eitaro MIYAKE, Hyogo-ken (JP)

(73) Assignee: Kabushiki Kaisha Toshiba, Tokyo (JP)

(21) Appl. No.: 13/423,137

(22) Filed: Mar. 16, 2012

(30) Foreign Application Priority Data
Mar. 22, 2011 (JP) 2011-063315

(51) Int. Cl. H01L 23/495; H01L 21/56

(52) U.S. Cl. 257/676; 438/123; 257/E23.031; 257/E21.504

(57) ABSTRACT

A semiconductor apparatus includes a semiconductor device, a bed, a plurality of leads, a suspension pin, and a mold resin. The bed includes an alignment pin provided in a peripheral portion of the bed. The semiconductor device is mounted on the bed via a first solder. The plurality of leads are electrically connected to a plurality of electrodes of the semiconductor device. The suspension pin is made of the same conductive material as the lead. The suspension pin has an alignment hole in a tip of the suspension pin. The suspension pin engages the peripheral portion of the bed by the alignment pin being inserted into the alignment hole. The suspension pin is fixed to the peripheral portion of the bed by a second solder. The mold resin contains the semiconductor device, the bed, one end of the leads, and the suspension pin.

### CROSS-REFERENCE TO RELATED APPLICATION

This application is based upon and claims the benefit of priority from the prior Japanese Patent Application No. 2011-063315, filed on Mar. 22, 2011; the entire contents of which are incorporated herein by reference.

### FIELD

Embodiments described herein relate generally to a semiconductor apparatus including a bed on which a semiconductor device is mounted, leads for drawing out electrodes of the semiconductor device, and a mold resin to seal the bed and the leads, and a method for manufacturing the same.

### BACKGROUND

Semiconductor apparatuses including a bed on which a semiconductor device is mounted, leads for drawing out electrodes of the semiconductor device to external circuit terminals, and a mold resin to seal the bed and the leads include, for example, SOPs (Small Outline Packages), QFPs (Quad Flat Packages), and the like. It is necessary to improve the heat dissipation of such semiconductor apparatuses. To improve the heat dissipation, the surface on the side of the bed opposite to the surface on which the semiconductor device is mounted is exposed from the mold resin. It is desirable for the bed to be thicker to further improve the heat dissipation by increasing the transitional heat conduction. However, in a normal assembly process of the semiconductor apparatus, the bed and the leads are supplied by using a leadframe in which the bed and the leads extend from a frame as a single body. Prior to completing the assembly of the semiconductor apparatus, the bed which is linked to the frame by suspension pins and the leads which are linked directly to the frame are trimmed from the leadframe by a die. In such a case, if the leads and the bed are too thick, the life of the die is shortened, which leads to higher costs of the manufacturing processes. Therefore, apparatuses are used in which the bed and the leads are made into a single body by separately preparing a leadframe in which the suspension pins and the leads are thin and a bed which is thicker than the leadframe and by caulking the tips of the suspension pins to the peripheral portion of the bed. However, the processing cost of fixing the bed and the leads by caulking also greatly affects the manufacturing cost of the semiconductor apparatus. Further reduction of the processing costs is desirable.

### BRIEF DESCRIPTION OF THE DRAWINGS

FIG. 1A is a plan view of a semiconductor apparatus according to a first embodiment.

FIG. 1B is a cross-sectional view of line A-A of FIG. 1A.

FIG. 2A is a plan view of a portion of the manufacturing processes of the semiconductor apparatus according to the first embodiment.

FIG. 2B is a cross-sectional view of line A-A of FIG. 2A.

FIG. 3A is a plan view of a portion of the manufacturing processes of the semiconductor apparatus according to the first embodiment.

FIG. 3B is a cross-sectional view of line A-A of FIG. 3A.

FIG. 4A is a plan view of a portion of the manufacturing processes of the semiconductor apparatus according to the first embodiment.

FIG. 4B is a cross-sectional view of line A-A of FIG. 4A.

FIG. 5A is a plan view of a portion of the manufacturing processes of the semiconductor apparatus according to the first embodiment.

FIG. 5B is a cross-sectional view of line A-A of FIG. 5A.

FIG. 6A is a plan view of a semiconductor apparatus according to a second embodiment.

FIG. 6B is a cross-sectional view of line A-A of FIG. 6A.

FIG. 7A is a plan view of a portion of the manufacturing processes of the semiconductor apparatus according to the second embodiment.

FIG. 7B is a cross-sectional view of line A-A of FIG. 7A.

FIG. 8A is a plan view of a portion of the manufacturing processes of the semiconductor apparatus according to the second embodiment.

FIG. 8B is a cross-sectional view of line A-A of FIG. 8A.

FIG. 9A is a plan view of a portion of the manufacturing processes of the semiconductor apparatus according to the second embodiment.

FIG. 9B is a cross-sectional view of line A-A of FIG. 9A.

FIG. 10A is a plan view of a portion of the manufacturing processes of the semiconductor apparatus according to the second embodiment.

FIG. 10B is a cross-sectional view of line A-A of FIG. 10A.

### DETAILED DESCRIPTION

A semiconductor apparatus includes a semiconductor device, a bed, a plurality of leads, a suspension pin, and a mold resin. The semiconductor device includes a plurality of electrodes. The bed includes an alignment pin provided in a peripheral portion of the bed. The semiconductor device is mounted on the bed via a first solder. The peripheral portion is provided around the semiconductor device. The bed is conductive. The plurality of leads extend outward from the bed. The plurality of leads are electrically connected to the plurality of electrodes of the semiconductor device. The suspension pin is made of the same conductive material as the lead. The suspension pin has an alignment hole in a tip of the suspension pin. The suspension pin engages the peripheral portion of the bed by the alignment pin being inserted into the alignment hole. The suspension pin is fixed to the peripheral portion of the bed by a second solder. The mold resin contains the semiconductor device, the bed, one end of the leads, and the suspension pin. One other end of the leads extends to protrude outside the mold resin.

Embodiments of the invention will now be described with reference to the drawings. The drawings used in the description of the embodiments are schematic for ease of description. In actual implementation, the configurations, the dimensions, the size relationships, and the like of the components in the drawings are not always limited to those illustrated in the drawings and are modifiable as appropriate within ranges in which the effects of the invention are obtained. Although the semiconductor apparatus packaged in a mold resin that is described in the examples is a SOP 8 including a chip of a power semiconductor device such as a MOSFET (Metal Oxide Semiconductor Field Effect Transistor), an IGBT (the Insulated Gate Bipolar Transistor), etc., as the semiconductor device, this is applicable also to semiconductor apparatuses of other resin packages such as QFPs, etc. Although the semiconductor device in the examples is described as a semiconductor chip such as a MOSFET, an IGBT, etc., the semiconductor device is not limited to being a semiconductor chip; and it is of course possible for the semiconductor device to include a multi-chip module or an interconnect substrate in which an interconnect pattern, electrode pads, and devices such as semiconductor chips, condensers, resistors, and the like are formed in a surface of the interconnect substrate. The semiconductor chip is not limited to discrete semiconductors such as MOSFETs, IGBTs, etc.; and the invention may be applied to an IC (Integrated Circuit) chip and the like in the case where heat generation is problematic for the semiconductor device.

### First Embodiment

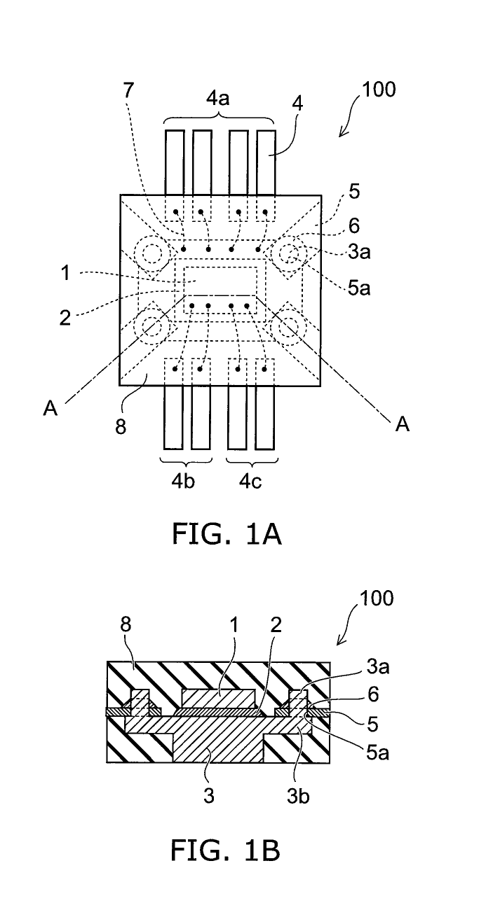

A first embodiment will now be described using FIGS. 1A and 1B. FIG. 1A is a plan view of a semiconductor apparatus according to the first embodiment; and FIG. 1B is a cross-sectional view of line A-A of FIG. 1A. The plan view inside a mold resin 8 of FIG. 1A is illustrated as a perspective view.

As illustrated in FIGS. 1A and 1B, the semiconductor apparatus 100 according to this embodiment includes a semiconductor device 1, a bed 3, multiple leads 4, a suspension pin 5, and the mold resin 8. The semiconductor device 1 is, for example, a chip of a power semiconductor device such as a MOSFET, an IGBT, etc., and includes not-illustrated multiple electrodes, e.g., a source electrode, a drain electrode, and a gate electrode. As an example, the source electrode and the gate electrode are formed in the front surface of the semiconductor device 1; and the drain electrode is formed in the back surface of the semiconductor device 1 (not illustrated). The back surface of the semiconductor device 1 is electrically connected via solder 2 (a first solder) to the front surface (a first major surface) of the bed 3 which is made of a conductive material. In other words, the drain electrode of the semiconductor device 1 is electrically connected to the bed 3 by the back surface of the semiconductor device 1 being soldered to the front surface of the bed 3. For example, copper and aluminum may be used as the material of the bed 3.

The bed 3 includes an alignment pin 3a in a peripheral portion 3b of the bed 3 to protrude on the front surface side (the first major surface side). In the case of this embodiment, the bed 3 has a rectangular configuration and includes the alignment pins 3a at the four corners of the rectangular configuration. The portion of the bed 3 where the semiconductor device 1 is mounted is formed to be thicker than the peripheral portion. Therefore, the bed 3 has a back surface (a second major surface) protruding from the peripheral portion on the side opposite to the front surface. Herein, unless otherwise noted, the thickness of the bed 3 refers to the thickness of the portion of the bed where the semiconductor device 1 is mounted. In other words, the thickness of the bed 3 refers to the spacing between the front surface (the first major surface) and the back surface (the second major surface) of the bed 3.

The multiple leads 4 extend outward from the bed. Because a SOP 8 is illustrated as an example in this embodiment, four leads extend outward from one side of the bed and another four leads extend outward from one other side of the bed on the side opposite to the one side. The four leads 4a that extend outward from the one side recited above are electrically connected to the bed 3 via, for example, bonding wires 7 and are electrically connected to the not-illustrated drain electrode formed in the back surface of the semiconductor device 1 via the first solder 2. Or, the four leads 4a that extend outward from the one side recited above may be formed as a single body with the bed 3 and may be formed to protrude outward from the one side of the peripheral portion 3b of the bed 3 recited above (not illustrated). Two leads 4b of the four leads that extend outward from the one other side recited above are electrically connected by the bonding wires 7 to not-illustrated source electrodes formed in the front surface of the semiconductor device 1; and the other two leads 4c are electrically connected by the bonding wires 7 to not-illustrated gate electrodes formed in the front surface of the semiconductor device 1. Although the electrical connections from the leads to the source electrodes, the drain electrode, and the gate electrodes are illustrated as bonding wires, it is also possible to perform the electrical connections using a conductor called a strap that has a band configuration or a rectangular configuration and is made of aluminum, copper, and the like instead of the bonding wire.

The suspension pin 5 has an alignment hole 5a in the tip of the suspension pin 5 and is made of the same conductive material as the multiple leads. Aluminum, copper, and the like may be used as the conductive material. The suspension pin 5 engages the peripheral portion of the bed 3 by the alignment pin 3a formed in the peripheral portion 3b of the bed 3 recited above being inserted into the alignment hole 5a. The suspension pin 5 is fixed to the peripheral portion 3b of the bed 3 by using solder 6 (second solder) to bond the portion of the tip of the suspension pin 5 in which the alignment hole 5a is made to the alignment pin 3a formed in the peripheral portion 3b of the bed 3. The suspension pin 5 is supplied from the same leadframe as the multiple leads 4; and the suspension pin 5 and the multiple leads 4 are formed from the same material and are formed with the same thickness. The thickness of the bed 3 is formed to be thicker than the leads 4 and the suspension pin 5. Similarly to the leads 4 and the suspension pin 5, aluminum, copper, and the like may be used as the material of the bed 3. As described in the manufacturing method described below, it is desirable for the leads 4 and the suspension pin 5 to be formed to be thin for easier trimming by the die; and it is desirable for the bed 3 to be formed to be thick to improve the heat dissipation of the semiconductor device 1.

The mold resin 8 is formed to contain the semiconductor device 1, the bed 3, the leads 4, and the suspension pin 5 in the interior of the mold resin 8. The semiconductor device 1 is completely buried inside the mold resin 8. The front surface (the first major surface) where the semiconductor device is mounted, the alignment pin 3a, and the peripheral portion 3b of the bed 3 are covered with the mold resin; and only the second major surface protruding from the peripheral portion 3b is exposed to the outside without being covered with the mold resin. The suspension pin 5 is buried inside the mold resin 8; and the portion of the suspension pin 5 exposed from the mold resin 8 is cut off.

The semiconductor apparatus 100 according to this embodiment configured as described above has the following features. The suspension pin 5 engages the peripheral portion of the bed 3 by the alignment pin 3a which is formed in the peripheral portion 3b of the bed 3 recited above being inserted into the alignment hole 5a. The suspension pin 5 is fixed to the peripheral portion 3b of the bed 3 by using the solder 6 (the second solder) to bond the portion of the tip of the suspension pin 5 in which the alignment hole 5a is made to the alignment pin 3a formed in the peripheral portion 3b of the bed 3. By the suspension pin 5 and the bed 3 having the configuration recited above, the semiconductor apparatus 100 according to this embodiment can include a bed 3 that is thicker than the leads 4 and the suspension pin 5 while suppressing higher manufacturing costs as described in the manufacturing method described below. As a result, the heat generated by the semiconductor device 1 during operation is efficiently dissipated out of the semiconductor apparatus 100 by being conducted to the bed 3 from the back surface of the semiconductor device 1 and by being dissipated from the back surface of the bed 3 which is exposed from the mold resin 8. The dissipation of the semiconductor apparatus 100 can be improved further because the transitional thermal resistance decreases as the thickness of the bed 3 increases.

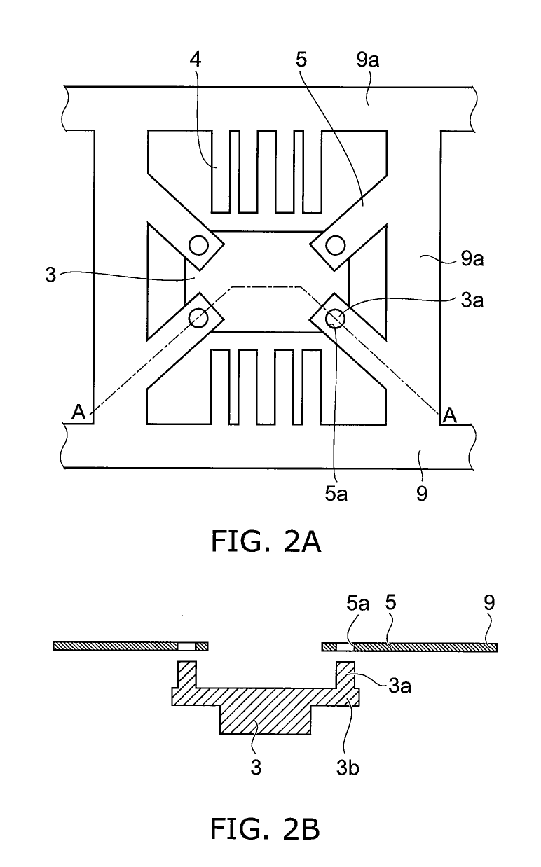

A method for manufacturing the semiconductor apparatus 100 will now be described using FIG. 2A to FIG. 5B. In the drawings of FIG. 2A to FIG. 5B, drawing A is a plan view of a portion of the manufacturing processes of the semiconductor apparatus 100 according to the first embodiment; and drawing B is a cross-sectional view of line A-A of drawing A. The semiconductor apparatus 100 according to this embodiment is manufactured as follows.

First, as illustrated in FIGS. 2A and 2B, a leadframe 9 is prepared in which multiple leads 4 (eight leads as an example in this embodiment) and multiple suspension pins 5 (four suspension pins as an example in this embodiment) are included inside a frame 9a having an annular configuration (e.g., a quadrilateral) for each device unit. The leadframe 9 includes multiple device units. Four of the eight leads 4 extend inside the frame 9a from one side of the frame; and the remaining four leads extend inside the frame 9a from one other side of the frame that opposes the one side recited above. A space for disposing the bed 3 described below is provided between the leads 4 extending from the one side of the frame 9a and the leads extending from the opposing one other side of the frame 9a. The suspension pins 5 are formed to extend from the frame 9a toward the space where the bed 3 is to be disposed. In this embodiment, two suspension pins extend from two end portions of a second one side that is orthogonal to the one side of the frame 9a from which the leads 4 extend; and two suspension pins extend from two ends of a second one other side that opposes the second one side. The arrangement of the suspension pins 5 and the leads 4 recited above is one example; and the structure is not limited to the structure recited above as long as the suspension pins 5 extend from the frame 9a and can support the bed 3. The alignment hole 5a is provided in the tip portion of the suspension pin 5 on the side of the suspension pin 5 opposite to the frame 9a. The leadframe 9 is made of aluminum or copper; and the leads 4, the suspension pins 5, and the frame 9a are formed to be uniformly thin.

The bed 3 is prepared. As described above, the bed 3 has a rectangular configuration and includes the alignment pins 3a at the four corners of the peripheral portion 3b of the bed 3 to protrude on the first major surface side where the semiconductor device 1 is mounted. The bed 3 is formed such that the portion where the semiconductor device 1 is mounted is thicker than the peripheral portion 3b; and the bed 3 has a second major surface protruding from the peripheral portion 3b on the side opposite to the first major surface on which the semiconductor device 1 is mounted.

The suspension pins 5 of the leadframe 9 engage the peripheral portion 3b of the bed 3 by the four alignment pins 3a formed in the peripheral portion 3b of the bed 3 recited above being inserted respectively into the corresponding alignment holes 5a of the suspension pins 5. By this engagement, the leadframe 9 is temporarily fixed on the first major surface side of the peripheral portion 3b of the bed 3 such that the bed 3 is disposed between the leads 4 extending from the one side of the frame 9a and the leads 4 extending from the one other side of the frame 9a that opposes the one side. Because positional shifting of the leadframe 9 and the bed 3 occurs in the process of packaging the mold resin described below in such a state, the leadframe 9 and the bed 3 are fixed by the solder 6 as described below.

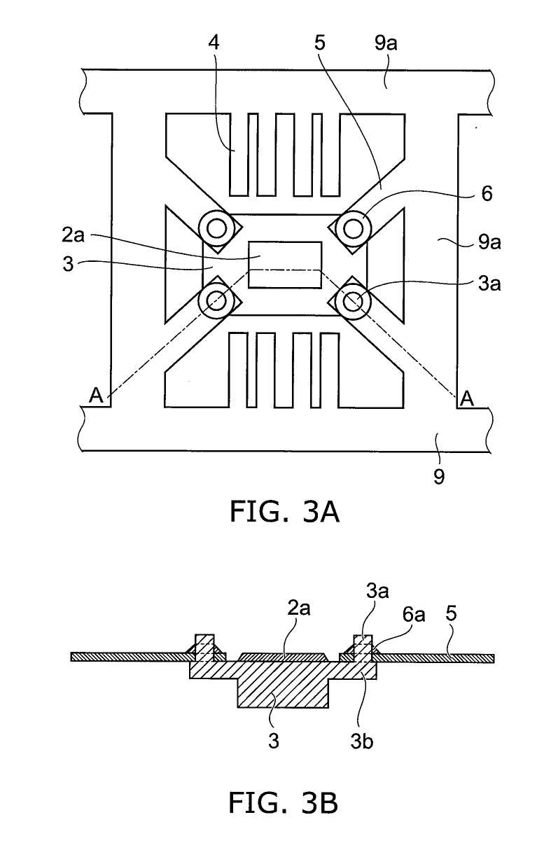

Then, as illustrated in FIGS. 3A and 3B, a first solder paste 2a is coated onto the portion of the first major surface of the bed 3 where the semiconductor device 1 is to be mounted. Then, the alignment pins 3a of the bed 3 are closely adhered to the portions of the suspension pins 5 where the alignment holes 5a are made by coating a second solder paste 6a onto portions of the tips of the suspension pins 5 where the alignment holes 5a are made.

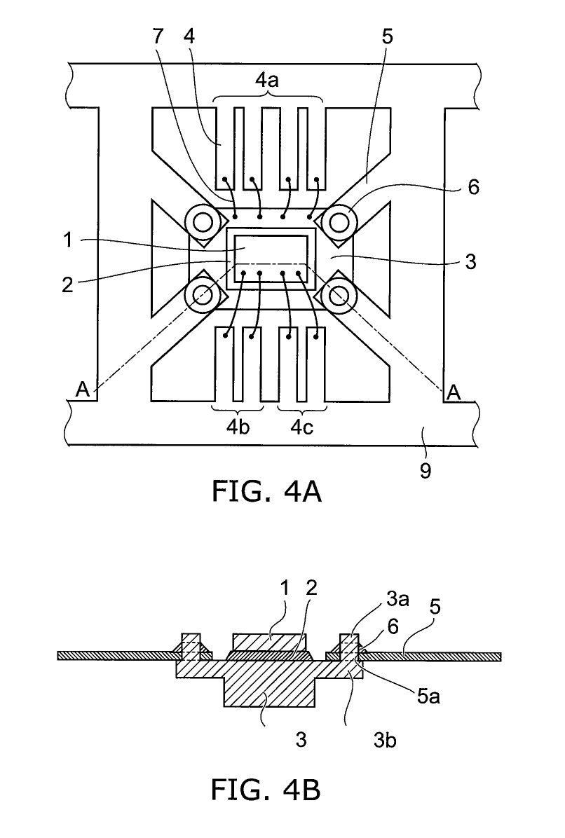

Continuing as illustrated in FIGS. 4A and 4B, the semiconductor device 1 is mounted to the first major surface of the bed 3 via the first solder paste 2a. The first solder paste 2a closely adheres to the first major surface of the bed 3 and the not-illustrated drain electrode formed in the back surface of the semiconductor device 1. Subsequently, the first solder paste 2a and the second solder paste 6a are simultaneously melted and solidified by a reflow process. Thereby, the portions of the suspension pins 5 where the alignment holes 5a are made are bonded to the alignment pins 3a of the peripheral portion 3b of the bed 3 by the second solder 6 simultaneously with the semiconductor device 1 being bonded to the first major surface of the bed 3 by the first solder 2. In other words, the leadframe 9 and the bed 3 become a single body by soldering simultaneously with the semiconductor device 1 being bonded by soldering to the first major surface of the bed 3.

Then, the multiple electrodes of the semiconductor device 1 are electrically connected respectively to the multiple leads 4. In the semiconductor apparatus 100 of this embodiment, each of the leads 4a extending from the upper side of the frame 9a is electrically connected to the not-illustrated drain electrode of the semiconductor device 1 by being electrically connected to the first major surface of the bed 3 by the bonding wire 7. The leads 4b extending from the lower side of the frame 9a are electrically connected respectively to the not-illustrated source electrodes formed in the front surface of the semiconductor device 1 by the bonding wires 7. The leads 4c that similarly extend from the lower side of the frame 9a are electrically connected respectively to the not-illustrated gate electrodes formed in the front surface of the semiconductor device 1 by the bonding wires 7. Although the bonding wire is illustrated as an example of the electrical connection method, a strap that has a band configuration or a rectangular configuration and is made of aluminum, copper, and the like may be used instead of the bonding wire as described above.

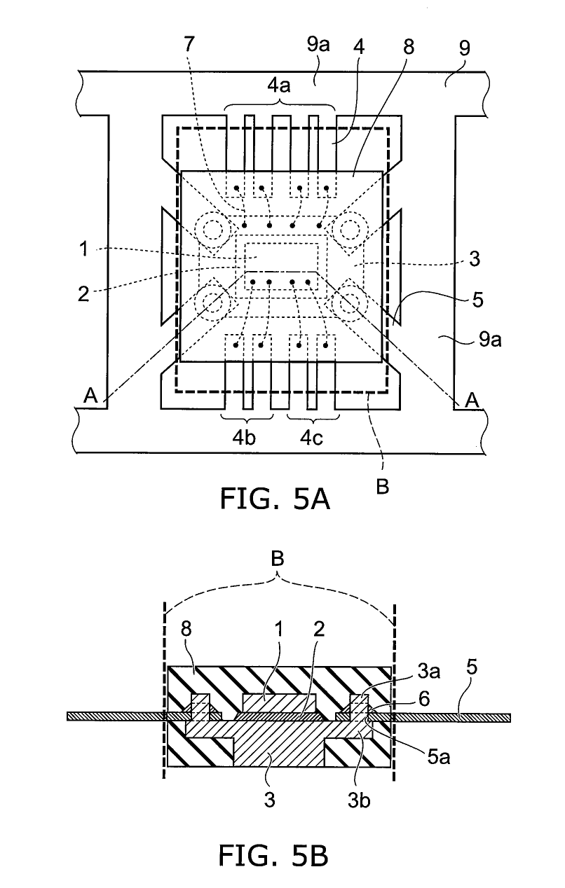

Continuing as illustrated in FIGS. 5A and 5B, the mold resin 8 is formed by a not-illustrated die to cover the semiconductor device, the bed, the bonding wires, a portion of the suspension pins, and one end of the leads. Here, the semiconductor device 1 is completely buried inside the mold resin 8. The front surface of the bed 3 where the semiconductor device 1 is mounted, the alignment pins 3a, and the peripheral portion 3b are covered with the mold resin; and only the second major surface protruding from the peripheral portion 3b is exposed to the outside without being covered with the mold resin.

Then, the leads 4 and the suspension pins 5 are trimmed from the frame 9a of the leadframe 9 at the position of broken line B of FIGS. 5A and 5B by a not-illustrated die. The portions of the multiple leads 4 that are electrically connected respectively to the electrodes of the semiconductor device 1 are buried in the interior of the mold resin 8; and the remaining portions extend outside the mold resin 8. The portions of the suspension pins 5 fixed to the peripheral portion 3b of the bed 3 by the second solder 6 are buried inside the mold resin 8; and the remaining portions of the suspension pins 5 do not extend outside the mold resin 8.

In the reflow process of the method for manufacturing the semiconductor apparatus 1 recited above according to the first embodiment, the portions of the suspension pins 5 where the alignment holes 5a are made are soldered to the peripheral portion 3b of the bed 3 simultaneously with the semiconductor device 1 being soldered to the first major surface of the bed 3. Thereby, the leadframe 9 that includes the leads 4 and the suspension pins 5 becomes a single body with the bed 3 that is thicker than the leadframe 9 prior to the formation of the mold resin 8. As a result, the mold resin 8 can be formed without the leads 4 shifting from the bed 3. The bed 3 and the leadframe 9 become a single body without needing a new process and without needing special processing of the leadframe 9 and the bed 3 because the bed 3 and the leadframe 9 become a single body simultaneously with the semiconductor device 1 being soldered to the first major surface of the bed 3 in the reflow process. Therefore, the manufacturing costs do not increase.

Conversely, although a detailed description is omitted, the following two comparative examples are conceivable as alternate technologies. The first comparative example is a method in which a rolled material is used to form a thick leadframe in which the bed 3, the leads 4, and the suspension pins 5 are a single body. Such a case has the disadvantage that the life of the die that trims the leads 4 and the suspension pins 5 from the leadframe 9 shortens because the stroke of the die during the trimming is long. In the case where this problem is avoided by the leadframe being formed using a rolled material such that the leads 4 and the suspension pins 5 are thinner than the bed 3, the processing cost of the rolled material undesirably increases. This leads to higher manufacturing costs. The second comparative example is a method in which a leadframe in which the leads 4 and the suspension pins 5 are formed as a single body is prepared separately from a bed 3 that is thicker than the leadframe as in this embodiment and the leadframe and the bed 3 become a single body by caulking the tips of the suspension pins to the peripheral portion of the bed 3. This also results in manufacturing costs that are higher than those of this embodiment due to the processing cost of the caulking.

Compared to these comparative examples, the semiconductor apparatus and the method for manufacturing the semiconductor apparatus according to this example can manufacture the semiconductor apparatus that uses the bed 3 that is thicker than the leads 4 without adding a special manufacturing process and incurring special processing costs. As a result, the heat dissipation of the semiconductor apparatus can be improved while suppressing higher manufacturing costs.

### Second Embodiment

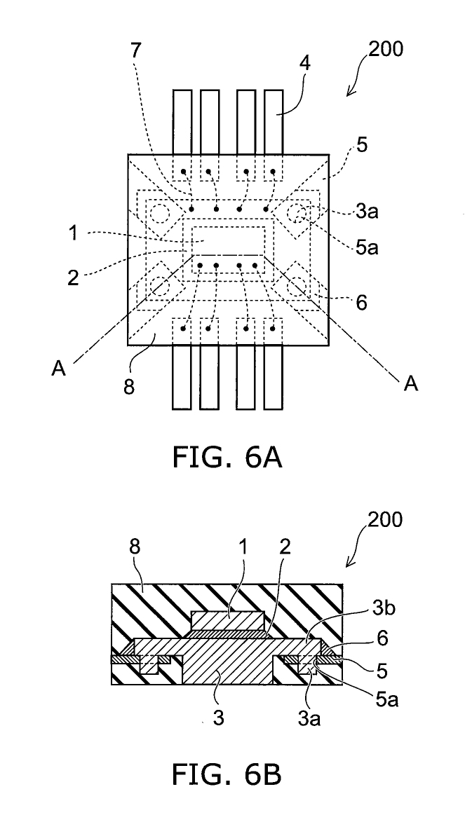

A semiconductor apparatus 200 according to a second embodiment will now be described using FIGS. 6A and 6B. FIG. 6A is a plan view of the semiconductor apparatus according to the second embodiment; and FIG. 6B is a cross-sectional view of line A-A of FIG. 6A. The plan view inside the mold resin 8 of FIG. 6A is illustrated as a perspective view. For portions having the same configurations as the configurations of the first embodiment, the same reference numeral or symbol is used and a description thereof is omitted. The points that differ from those of the first embodiment are mainly described.

As illustrated in FIGS. 6A and 6B, the semiconductor apparatus 200 according to this embodiment differs from the semiconductor apparatus 100 according to the first embodiment in that the alignment pins 3a formed in the peripheral portion 3b of the bed 3 are formed to protrude on the second major surface side which is opposite to the first major surface on which the semiconductor device 1 is mounted. Otherwise, the semiconductor apparatus 200 has the same structure as the semiconductor apparatus 100 according to the first embodiment.

In other words, the bed 3 includes the alignment pins 3a in the peripheral portion 3b to protrude on the second major surface side which is opposite to the first major surface. Similarly to the first embodiment, the bed 3 has a rectangular configuration and includes the alignment pins 3a at the four corners of the rectangular configuration. The bed 3 is formed such that the portion where the semiconductor device 1 is mounted is thicker than the peripheral portion 3b. Therefore, the bed 3 has the second major surface protruding from the peripheral portion on the side opposite to the front surface.

The suspension pin 5 has the alignment hole 5a at the tip portion of the suspension pin 5 and is made of the same conductive material as the multiple leads 4. The suspension pin 5 engages the peripheral portion of the bed 3 by the alignment pin 3a that is formed in the peripheral portion 3b of the bed 3 recited above being inserted into the alignment hole 5a. The suspension pin 5 is fixed to the peripheral portion 3b of the bed 3 by using the solder 6 (the second solder) to bond the portion of the tip of the suspension pin 5 in which the alignment hole 5a is made to one side wall of the four corners of the peripheral portion 3b of the bed 3.

In the semiconductor apparatus 200 according to this embodiment as well, similarly to the semiconductor apparatus 100 according to the first embodiment, the suspension pin 5 engages the peripheral portion of the bed 3 by the alignment pin 3a formed in the peripheral portion 3b of the bed 3 recited above being inserted into the alignment hole 5a. The suspension pin 5 is fixed to the peripheral portion 3b of the bed 3 by using the solder 6 (the second solder) to bond the portion of the tip of the suspension pin 5 in which the alignment hole 5a is made to one side wall of the four corners of the peripheral portion 3b of the bed 3. Similarly to the semiconductor apparatus 100 according to the first embodiment, the semiconductor apparatus 200 according to this embodiment also can include a bed 3 that is thicker than the leads 4 and the suspension pin 5 while suppressing higher manufacturing costs. As a result, the heat generated by the semiconductor device 1 during operation is efficiently dissipated out of the semiconductor apparatus 100 by being conducted to the bed 3 from the back surface of the semiconductor device 1 and by being dissipated from the back surface of the bed 3 which is exposed from the mold resin 8.

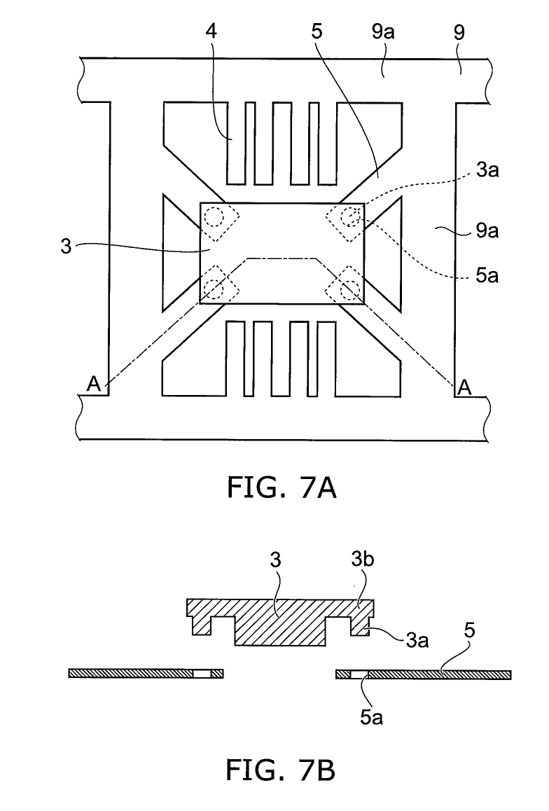

A method for manufacturing the semiconductor apparatus 200 according to this embodiment will now be described using FIG. 7A to FIG. 10B. Unless otherwise noted, the features are the same as those of the method for manufacturing the semiconductor apparatus 100 according to the first embodiment. In FIG. 7A to FIG. 10B, drawing A is a plan view of a portion of the manufacturing processes of the semiconductor apparatus 200 according to the first embodiment; and drawing B is a cross-sectional view of line A-A of drawing A. The semiconductor apparatus 100 according to this embodiment is manufactured as follows.

First, as illustrated in FIGS. 7A and 7B, similarly to the first embodiment, the leadframe 9 that includes the multiple leads 4 and the suspension pins 5 is prepared. The bed 3 is prepared. The bed 3 has a rectangular configuration and includes the alignment pins 3a at the four corners of the peripheral portion 3b of the bed 3 to protrude on the side opposite to the first major surface on which the semiconductor device 1 is mounted. The bed 3 is formed such that the portion where the semiconductor device 1 is mounted is thicker than the peripheral portion 3b and has the second major surface protruding from the peripheral portion 3b on the side opposite to the first major surface on which the semiconductor device 1 is mounted.

The suspension pins 5 of the leadframe 9 engage the peripheral portion 3b of the bed 3 by the four alignment pins 3a formed in the peripheral portion 3b of the bed 3 recited above being respectively inserted into the corresponding alignment holes 5a of the suspension pins 5. By this engagement, the leadframe 9 is temporarily fixed on the second major surface side of the peripheral portion 3b of the bed 3 such that the bed 3 is disposed between the leads 4 extending from the one side of the frame 9a and the leads extending from the one other side of the frame 9a that opposes the one side.

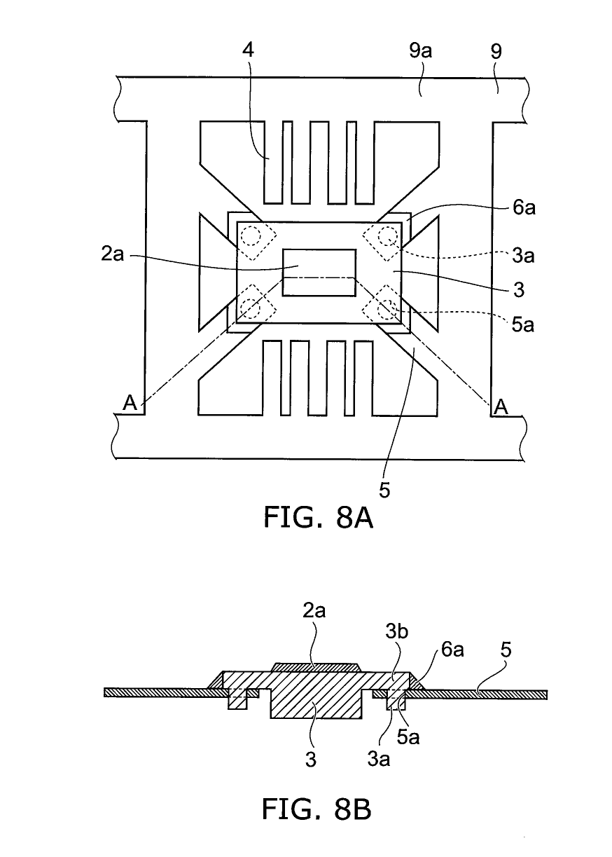

Then, as illustrated in FIGS. 8A and 8B, the first solder paste 2a is coated onto the portion of the first major surface of the bed 3 where the semiconductor device 1 is to be mounted. Then, the second solder paste 6a is coated onto the portion of the tip of the suspension pin 5 where the alignment hole 5a is made to closely adhere to one side wall of the four corners of the peripheral portion 3b of the bed 3 and the portion of the suspension pin 5 where the alignment hole 5a is made.

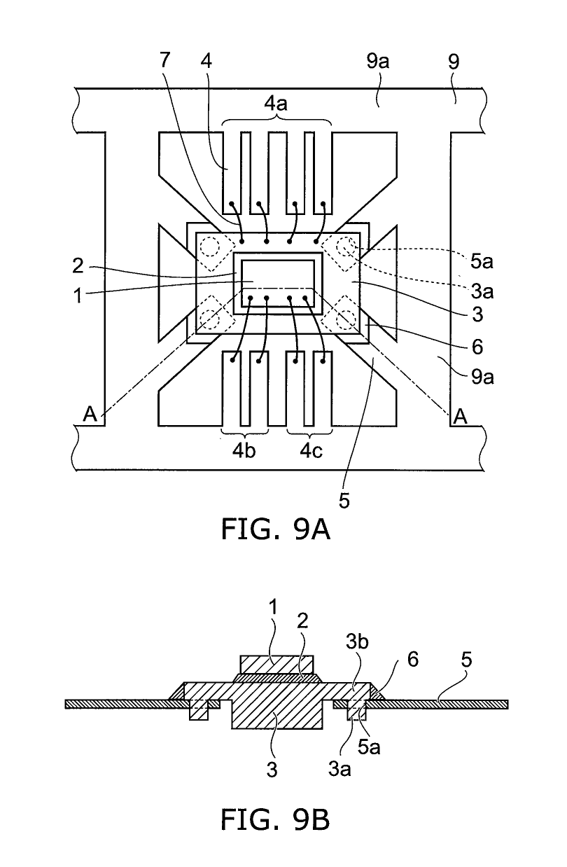

Then, as illustrated in FIGS. 9A and 9B, the semiconductor device 1 is mounted to the first major surface of the bed 3 via the first solder paste 2a. The first solder paste 2a closely adheres to the first major surface of the bed 3 and the not-illustrated drain electrode formed in the back surface of the semiconductor device 1. Subsequently, the first solder paste 2a and the second solder paste 6a are simultaneously melted and solidified by a reflow process. Thereby, the side walls of the four corners of the peripheral portion 3b of the bed 3 are bonded to the portions of the suspension pins 5 where the alignment holes 5a are made by the second solder 6 simultaneously with the semiconductor device 1 being bonded to the first major surface of the bed 3 by the first solder 2. In other words, the leadframe 9 and the bed 3 become a single body by soldering simultaneously with the semiconductor device 1 being bonded by soldering to the first major surface of the bed 3.

Continuing similarly to the method for manufacturing the semiconductor apparatus 100 according to the first embodiment, the multiple electrodes of the semiconductor device 1 are electrically connected respectively to the multiple leads 4.

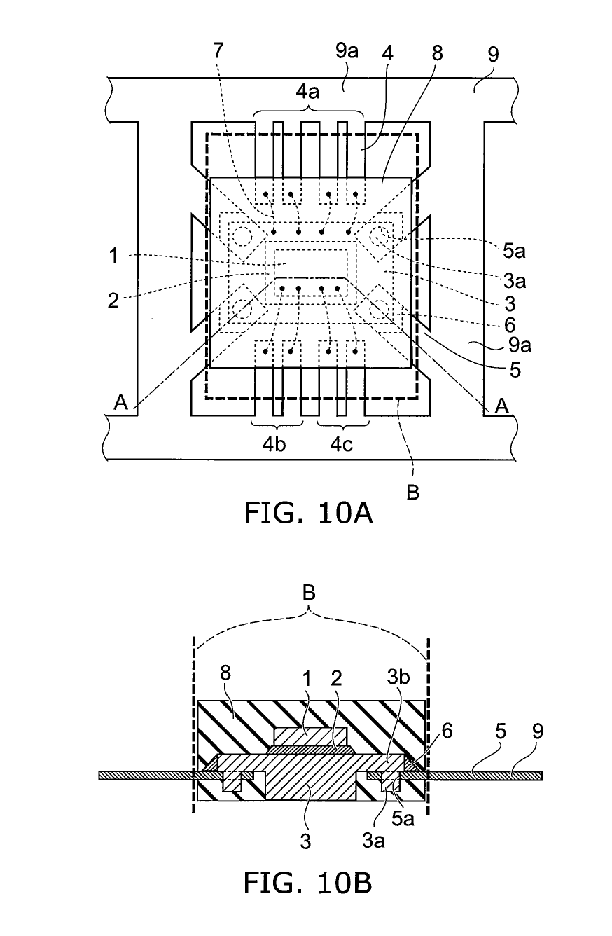

Then, similarly to the method for manufacturing the semiconductor apparatus 100 according to the first embodiment as illustrated in FIGS. 10A and 10B, the mold resin 8 is formed; and the leads 4 and the suspension pins 5 are trimmed from the frame 9a of the leadframe 9.

Similarly to the first embodiment, in the method for manufacturing the semiconductor apparatus 2 recited above according to the second embodiment, the peripheral portion 3b of the bed 3 is soldered to the portions of the suspension pins 5 where the alignment holes 5a are made simultaneously with the semiconductor device 1 being soldered to the first major surface of the bed 3 in the reflow process. Thereby, the leadframe 9 that includes the leads 4 and the suspension pins 5 and the bed 3 that is thicker than the leadframe 9 become a single body prior to the formation of the mold resin 8. As a result, the mold resin 8 can be formed without the leads 4 shifting from the bed 3. The bed 3 and the leadframe 9 become a single body without needing a new process and without needing special processing of the leadframe 9 and the bed 3 because the bed 3 and the leadframe 9 become a single body simultaneously with the semiconductor device 1 being soldered to the first major surface of the bed 3 in the reflow process. Therefore, the manufacturing costs do not increase. In the method for manufacturing the semiconductor apparatus 200 according to this embodiment as well, the heat dissipation of the semiconductor apparatus can be improved while suppressing higher manufacturing costs.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor apparatus, comprising:
a semiconductor device including a plurality of electrodes;
a bed including an alignment pin provided in a peripheral portion of the bed, the semiconductor device being mounted on the bed via a first solder, the peripheral portion being provided around the semiconductor device, the bed being conductive;
a plurality of leads extending outward from the bed, the plurality of leads being electrically connected to the plurality of electrodes of the semiconductor device;
a suspension pin made of the same conductive material as the lead, the suspension pin having an alignment hole in a tip of the suspension pin, the suspension pin engaging the peripheral portion of the bed by the alignment pin being inserted into the alignment hole; and
a mold resin containing the semiconductor device, the bed, one end of the leads, and the suspension pin, one other end of the leads extending to protrude outside the mold resin,
the suspension pin being fixed to the peripheral portion of the bed by a second solder.

2. The apparatus according to claim 1, wherein a thickness of the suspension pin is the same as a thickness of the leads.

3. The apparatus according to claim 1, wherein the bed is thicker than the leads.

4. The apparatus according to claim 1, wherein the peripheral portion including the alignment pin of the bed is thinner than a portion of the bed where the semiconductor device is mounted.

5. The apparatus according to claim 1, wherein the bed has a first major surface and a second major surface on a side opposite to the first major surface, the semiconductor device being mounted on the first major surface, the second major surface protruding from the peripheral portion.

6. The apparatus according to claim 5, wherein the alignment pin protrudes on the first major surface side.

7. The apparatus according to claim 6, wherein a portion of the suspension pin where the alignment hole is made is fixed to the alignment pin of the peripheral portion of the bed by the second solder.

8. The apparatus according to claim 5, wherein the alignment pin protrudes on the second major surface side.

9. The apparatus according to claim 8, wherein a portion of the suspension pin where the alignment hole is made is fixed to a side wall of the peripheral portion of the bed by the second solder.

10. The apparatus according to claim 5, wherein the second major surface of the bed is exposed from the mold resin.

11. The apparatus according to claim 1, wherein: the semiconductor device includes an interconnect substrate; and the electrodes, an interconnect layer, and a semiconductor chip are formed in a surface of the interconnect substrate.

12. A method for manufacturing a semiconductor apparatus, comprising:
causing a suspension pin of a leadframe to engage a peripheral portion of a bed by inserting an alignment pin provided in the peripheral portion of the bed into an alignment hole provided in a tip of the suspension pin of the leadframe, the leadframe including the suspension pin and a lead extending inward from a frame having an annular configuration, the bed being conductive;
coating a first solder paste onto a central portion of the bed;
coating a second solder paste onto the tip of the suspension pin to connect the tip of the suspension pin to the peripheral portion of the bed;
mounting a semiconductor device including a plurality of electrodes on the bed via the first solder paste;
fixing the tip of the suspension pin by soldering to the peripheral portion of the bed simultaneously with fixing the semiconductor device by soldering to the bed by performing reflow simultaneously for the first solder paste and the second solder paste;
electrically connecting the lead to the plurality of electrodes of the semiconductor device;
covering the semiconductor device, the bed, a portion of the suspension pin, and one end of the lead with a mold resin; and
trimming the lead and the suspension pin from the frame having the annular configuration of the leadframe to leave the lead to extend outside the mold.

13. The method according to claim 12, wherein:
a thickness of the suspension pin is the same as a thickness of the lead; and
the bed is thicker than the lead.

14. The method according to claim 12, wherein the peripheral portion including the alignment pin of the bed is thinner than a portion of the bed where the semiconductor device is mounted.

15. The method according to claim 12, wherein the bed has a first major surface and a second major surface on a side opposite to the first major surface, the semiconductor device being mounted on the first major surface, the second major surface protruding from the peripheral portion.

16. The method according to claim 15, wherein the alignment pin protrudes on the first major surface side, and the causing of the suspension pin of the leadframe to engage the peripheral portion of the bed includes the alignment pin of the bed being inserted into the alignment hole of the suspension pin.

17. The method according to claim 16, wherein the coating of the second solder paste includes the second solder paste being coated to bond the alignment pin of the peripheral portion of the bed to a portion of the suspension pin where the alignment hole is made.

18. The method according to claim 15, wherein the alignment pin protrudes on the second major surface side, and the causing of the suspension pin of the leadframe to engage the peripheral portion of the bed includes the alignment pin of the bed being inserted into the alignment hole of the suspension pin.

19. The method according to claim 18, wherein the coating of the second solder paste includes the second solder paste being coated to bond a side wall of the peripheral portion of the bed to a portion of the suspension pin where the alignment hole is made.

20. The method according to claim 12, wherein: the semiconductor device includes an interconnect substrate; and the electrodes, an interconnect layer, and a semiconductor chip are formed in a surface of the interconnect substrate.
